(19) United States
(12) Patent Application Publication
(10) Pub. No.: US 2025/0062720 A1
(43) Pub. Date: Feb. 20, 2025

(54) AUTOMATED TESTING OF A PHOTOVOLTAIC POWER SYSTEM AND ASSOCIATED COMPONENTS USING AN OSCILLOSCOPE

(71) Applicant: Tektronix, Inc., Beaverton, OR (US)

(72) Inventors: Shubha B, Bengaluru (IN); Krishna N H Sri, Bengaluru (IN); Niranjan R. Hegde, Siddapur (IN); Vivek Shivaram, Bengaluru (IN)

(73) Assignee: Tektronix, Inc., Beaverton, OR (US)

(21) Appl. No.: 18/807,895

(22) Filed: Aug. 16, 2024

(30) Foreign Application Priority Data
Aug. 16, 2023 (IN) 202321054842

(51) Int. Cl. H02S 50/10; G01R 19/25

(52) U.S. Cl. CPC H02S 50/10; G01R 19/2509; G01R 19/2513

(57) ABSTRACT

An oscilloscope includes input channels for receiving at least one voltage signal and at least one current signal from at least one component of a photovoltaic power system under test (SUT), a user interface including a display and one or more controls for receiving one or more test configuration settings from a user, and one or more processors configured to acquire waveforms of the at least one voltage signal and the at least one current signal, and implement a photovoltaic power system compliance test module that automatically determines, in real-time, one or more SUT performance measurements based on the acquired voltage and current waveforms and the one or more test configuration settings, displays, in real-time, the one or more SUT performance measurements to the user on the display. Methods of performing automated hardware-in-the-loop testing of a photovoltaic power system under test using an oscilloscope are also disclosed.

### CROSS-REFERENCE TO RELATED APPLICATION

This application claims priority under 35 U.S.C. § 119 to Indian Provisional Pat. App. No. 202321054842, titled “AUTOMATION OF RENEWABLE ENERGY SYSTEM WORKFLOW AND ITS ASSOCIATED COMPONENTS USING OSCILLOSCOPES,” filed Aug. 16, 2023, the disclosure of which is hereby incorporated herein by reference in its entirety.

### TECHNICAL FIELD

This disclosure relates in general to power topologies and renewable energy systems, and more particularly, relates to automation of renewable energy system workflow and its associated components.

### BACKGROUND

In recent times, renewable energy system utilization is significantly increasing. To that effect, validation of the renewable energy system is to be carried out, prior to its deployment. Conventionally, designers typically relied on dedicated hardware such as solar array simulator for simulating solar power and providing input to grid tied inverter. Further, there is multiple dedicated hardware for photovoltaic (PV) array simulator (or the solar array simulator). However, the validation of Maximum Power point tracking (MPPT) function needs real-world testing using an actual solar array. These MPPT analysis include faithful tracking of maximum power, I-V characteristics, short and open conditions, partial radiance, different weather conditions and charge controller functionality check. At the moment, there is no such solution for real time validation/debug solution entailing all the parameters for PV array and charge controller system. Thus, designers rely on multi meters which does not give time domain and frequency domain waveforms. Further, conventional solutions include testing the workflow after the design stage. However, the conventional solution is time consuming, in case of occurrence of an error in the power topology. In addition, there is manual intervention with the requirement of additional hardware for rectifying the error.

Moreover, for inverters with anti-islanding testing, there are dedicated hardware such as Regenerative Grid Simulators. A grid simulator is a programmable AC power supply with option to emulate varying grid conditions to facilitate the testing. These grid simulators are used as power amplifier to complete power hardware in loop simulation. The simulation entails controlling grid simulator and inverter together with control signal being generated by another device like AFG/AWG. But most of the grid simulators have small screen indicating RMS values, Power quality parameters without time domain and phasor plots or frequency domain display. Few of the dedicated hardware having their own software, but the refresh rate of the waveforms is slow leading is slower real-time hardware simulation. Designer would like to simulate their testing condition in real time and measure Inverter efficiency, Power quality parameter and phasor plot in real time. In addition, the conventional workflows lack data security and processing in case of smart grids.

Therefore, there is a need for techniques for addressing the above-mentioned problems related to validating of workflow testing of renewable energy systems, phase tracking, and anti-islanding detection, in addition to providing other technical advantages.

### BRIEF DESCRIPTION OF THE DRAWINGS

FIG. 1 illustrates a simplified block diagram representation of a workflow for indoor testing of renewable energy system, in accordance with an embodiment of the present disclosure.

FIG. 2 illustrates a simplified block diagram representation of a workflow for outdoor testing of renewable energy systems, in accordance with an embodiment of the present disclosure.

FIG. 3 illustrates a simplified block diagram representation depicting various blocks involved in synchronization of renewable energy with grid, in accordance with an embodiment of the present disclosure.

FIG. 4 represents example configurations and results for testing the performance of a controller performing Maximum Power Point Tracking (MPPT) in a system under test, in accordance with an embodiment of the present disclosure.

FIG. 5 represents power versus voltage plot indicating MPPT point, in accordance with an embodiment of the present disclosure.

FIG. 6 represents voltage vs current plot created from accumulation of data from multiple acquisitions, in accordance with an embodiment of the present disclosure.

FIG. 7 represents modelling of MPPT data, in accordance with an embodiment of the present disclosure.

FIG. 8 represents example configurations of performing an efficiency measurement of at least one component of a system under test, in accordance with an embodiment of the present disclosure.

FIG. 9 represents input voltage versus efficiency curve, in accordance with an embodiment of the present disclosure.

FIG. 10 represents current versus efficiency curve, in accordance with an embodiment of the present disclosure.

FIG. 11 represents efficiency versus switching frequency curve, in accordance with an embodiment of the present disclosure.

FIG. 12 represents an anti-islanding measurements test setup, in accordance with an embodiment of the present disclosure.

FIG. 13 represents example harmonics measurements configurations and results, in accordance with an embodiment of the present disclosure.

FIG. 14 represents a Total Harmonic Distortion (THD) plot with limits validation to detect islanding, in accordance with an embodiment of the present disclosure.

FIG. 15 represents a simplified block diagram representation of a test setup for automation of measurements, in accordance with an embodiment of the present disclosure.

FIG. 16 represents a simplified block diagram of an oscilloscope for performing automated testing of a photovoltaic power system under test, in accordance with an embodiment of the present disclosure.

### DETAILED DESCRIPTION

In the following description, for purpose of explanation, specific details are set forth in order to provide an understanding of the present disclosure. It will be apparent, however, to one skilled in the art that the present disclosure may be practiced without these details. One skilled in the art will recognize that embodiments of the present disclosure, some of which are described below, may be incorporated into several systems.

The terms and words used in the following description and claims are not limited to the bibliographical meanings but are merely used by the inventor to enable a clear and consistent understanding of the invention. It is to be understood that the singular forms “a,” “an,” and “the” include plural referents unless the context clearly dictates otherwise.

References in the specification to “one embodiment” or “an embodiment” mean that a particular feature, structure, characteristic, or function described in connection with the embodiment is included in at least one embodiment of the invention. The appearances of the phrase “in one embodiment” in various places in the specification are not necessarily all referring to the same embodiment.

It should be noted that the description merely illustrates the principles of the present invention. It will thus be appreciated that those skilled in the art will be able to devise various arrangements that, although not explicitly described herein, embody the principles of the present invention. Furthermore, all examples recited herein are principally intended expressly to be only for explanatory purposes to help the reader in understanding the principles of the invention and the concepts contributed by the inventor to furthering the art and are to be construed as being without limitation to such specifically recited examples and conditions. Moreover, all statements herein reciting principles, aspects, and embodiments of the invention, as well as specific examples thereof, are intended to encompass equivalents thereof.

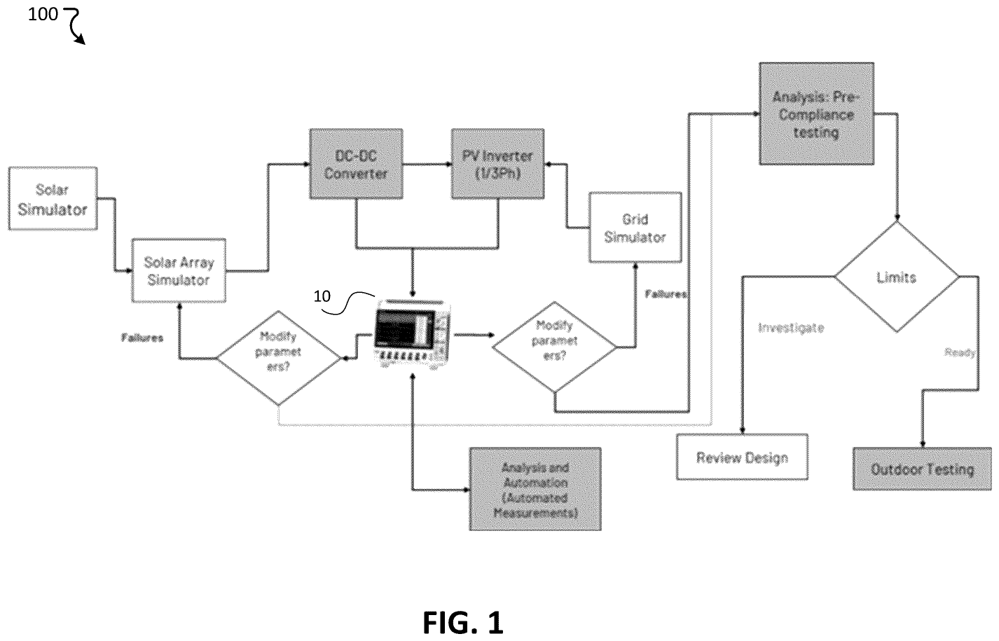

Various embodiments of the present disclosure are further described with reference to FIG. 1 to FIG. 16.

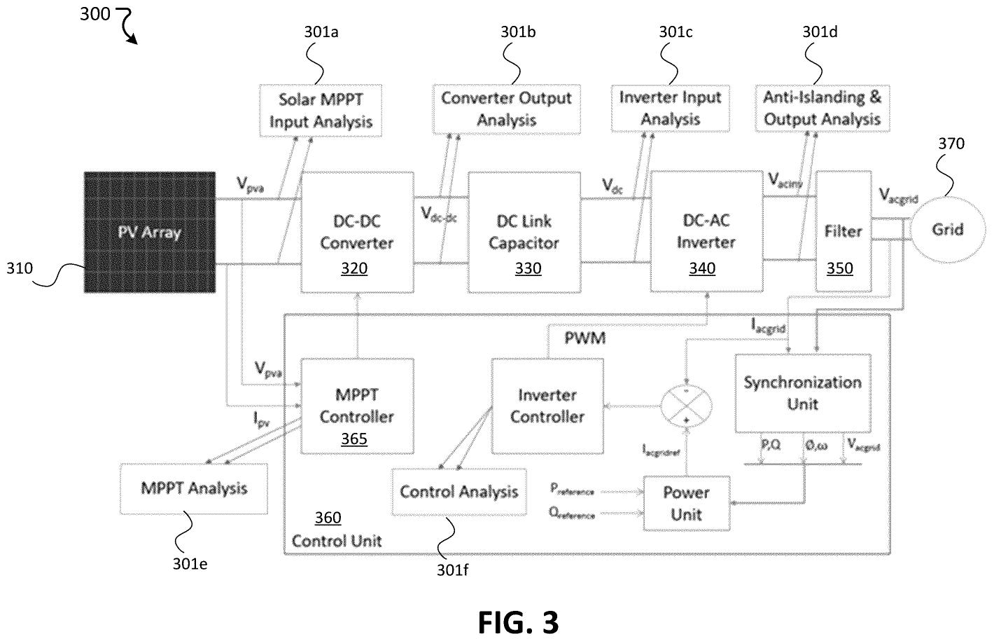

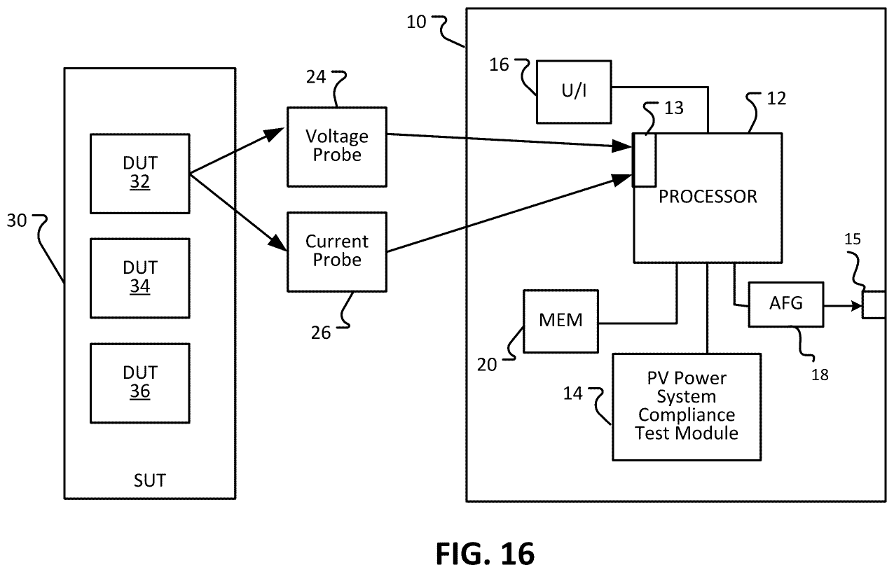

FIG. 16 shows an embodiment of a test and measurement instrument 10 for automated testing of a photovoltaic power system under test (SUT) 30. The SUT 30 may include multiple functional blocks, or components, such as components 32, 34, 36, which are discussed further below with respect to FIG. 3. In some embodiments, the test and measurement instrument 10 may be an oscilloscope, such as, for example, a Tektronix MSO 5 Series Mixed Signal Oscilloscope. The test and measurement instrument 10 receives one or more electrical signals from at least one component 32, 34, 36 of the SUT 30, through one or more probes 24, 26, at input channels 13. The received signal(s) may be single-ended or differential. The instrument 10 includes a sufficient number of input channels 13 for receiving the signals. An oscilloscope 10 according to embodiments may include, for example, eight input channels to receive up to eight signals from the SUT 30. The input channels 13 receive at least one voltage signal and at least one current signal form an input side or an output side of at least one component 32, 34, 36, of the SUT. A voltage signal is received through a voltage probe 24, such as a Tektronix THDP Series voltage probe, and a current signal is received through a current probe 26, such as a Tektronix TCP30A current probe.

The test and measurement instrument has one or more processors represented by processor 12, a memory 20, and a user interface 16. The memory may store executable instructions in the form of code that, when executed by the processor, causes the processor to perform tasks. The memory may also allow for storing acquired waveforms, measurement results, output files, plots, etc., as will be discussed in more detail later.

User interface 16 of the test and measurement instrument allows a user to interact with the instrument 10, such as to input settings, configure tests, etc. The user interface may include a display, for example to display analysis results to a user, and one or more controls to allow the user to select test configuration settings.

The one or more processors may execute code to implement the methods of the embodiments. In particular, the one or more processors cause the instrument 10 to sample and digitize each of the received voltage and/or current signals, and save each digitized signal, at least temporarily, into a portion of memory 20, as an acquired waveform. Furthermore, the one or more processors implement a photovoltaic (PV) power system compliance test module 14. The compliance test module 14 automatically determines, in real-time, one or more SUT performance measurements based on the acquired voltage and current waveforms and one or more test configuration settings entered by the user through the user interface 16, and displays, in real-time, the one or more SUT performance measurements to the user on the display of the user interface 16. Generally, the compliance test module 14 is designed to automatically perform a series of performance tests on individual components of, or on the entirety of, the PV SUT 30, as discussed in more detail below.

The instrument 10 may also include an internal arbitrary function generator (AFG) 18 that can generate signals, as instructed by the one or more processors 12. The AFG 18 is connected to an output port 15 to send the generated signal to another instrument or system external to instrument 10, as discussed in more detail below.

FIG. 1 illustrates a simplified block diagram representation of a workflow 100 for indoor testing of renewable energy system, in accordance with an embodiment of the present disclosure. To perform reproducible laboratory measurements, a PV array simulator (or the solar array simulator) is necessary that generates DC power with the I-V curve characteristic of a PV array. The inverter or grid-tied inverter designer can probe for voltage and current at the input side of the inverter. Thus, the fidelity of power received to inverter straight out of the PV array simulator or actual PV array with charge controller.

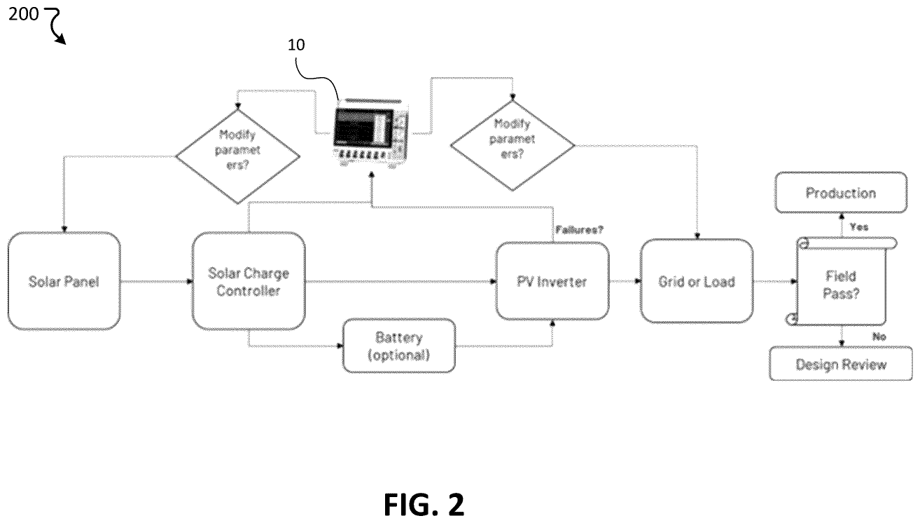

FIG. 2 illustrates a simplified block diagram representation of a workflow 200 for outdoor testing of renewable energy systems, in accordance with an embodiment of the present disclosure. It is to be noted that iterative debugging and analysis of the workflow for early detection of issues is performed. In addition, the workflow facilitates the automation of instruments such as solar and grid simulators, power supplies and oscilloscope.

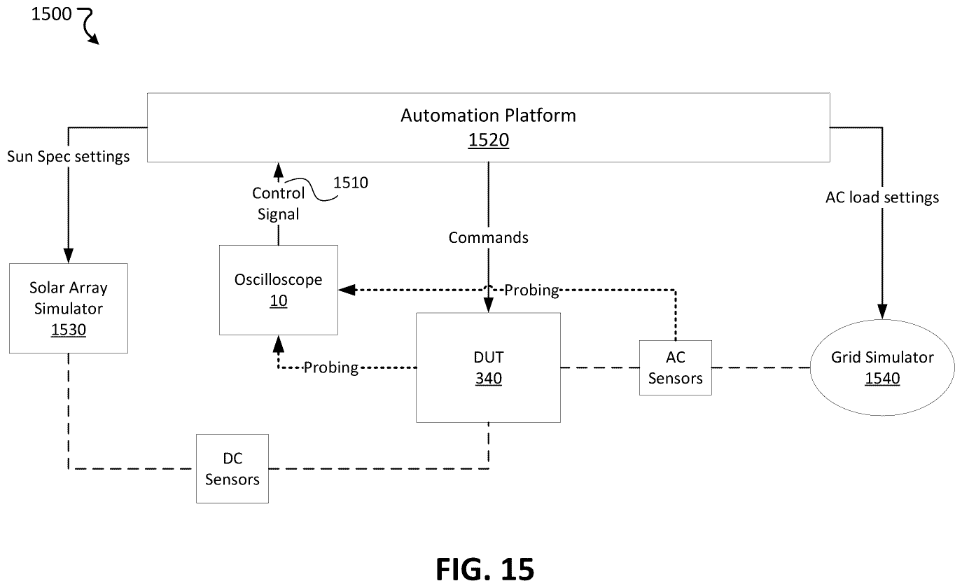

FIG. 3 illustrates a simplified block diagram of typical components of an example photovoltaic power system under test (SUT) 300. The SUT 300 may be an example of the SUT 30 in FIG. 16. As shown in FIG. 3, a typical photovoltaic power SUT 300 may include a PV Array 310. However, in some embodiments, the actual PV Array 310 may be replaced by a solar array simulator, such as shown in FIGS. 1 and 15. The PV Array 310 and/or solar array simulator may be connected to a DC-DC converter 320. The DC-DC converter 320 may be connected, optionally through a DC link capacitor 330 in some embodiments, to a DC-AC inverter 340. In the embodiment shown in FIG. 3, the DC-AC inverter is a Grid Tied Inverter (GTI), as it is connected to the electrical grid 370 through an optional filter 350. The SUT 300 may also include a controller 360. The controller 360 may perform various functions for the SUT, including synchronization, inverter control, and maximum power point tracking (MPPT), such as by MPPT Controller block 365. As discussed below with respect to FIG. 16, each of the analysis blocks 301a-301f is a potential point for probing a voltage and/or current signal on an input side or an output side of a component of the SUT 300. For example, a voltage signal and/or a current signal on the input side of DC-DC converter block 320 may be probed at location 301a, and a voltage signal and/or a current signal on the output side of DC-DC converter block 320 may be probed at location 301b.

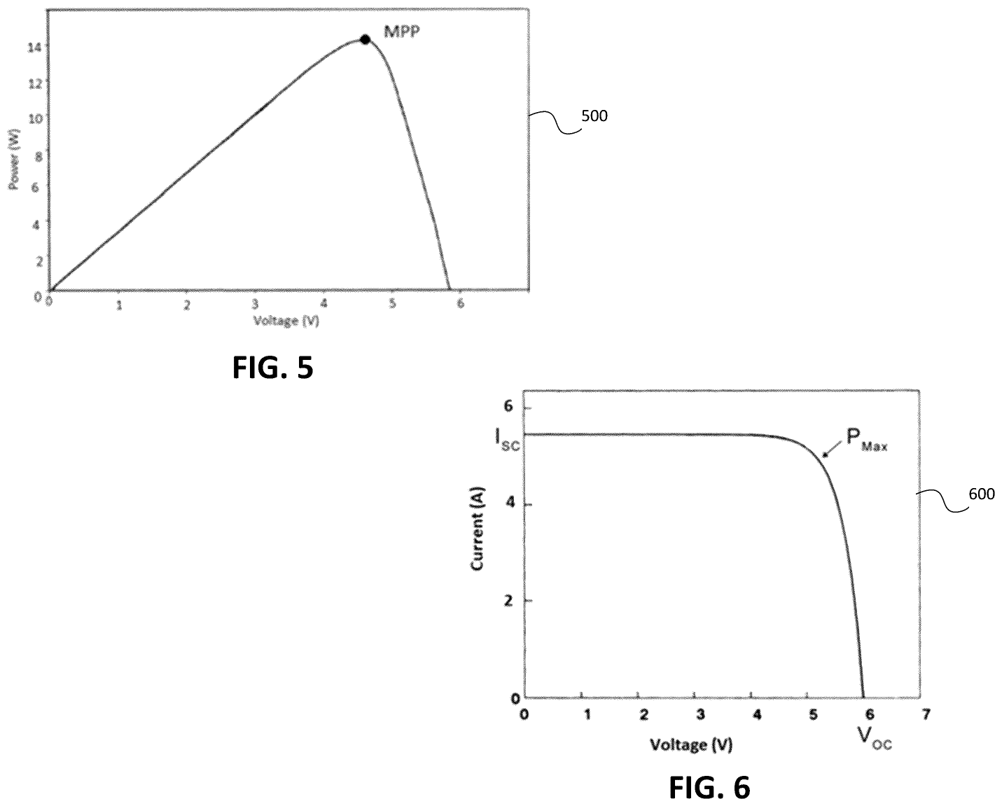

Referring to FIG. 3 in conjunction with FIG. 2, the workflow compares different methods of synchronization with the grid, specifically for the acquired waveforms, and helps the user to select the best method. It is to be noted that Maximum power point tracking (MPPT) is performed by some battery charge controllers and by most grid-connected PV inverters. In other words, MPPT is an algorithm that is included in charge controllers for extracting the maximum available power from PV modules under certain conditions. The concept is to adjust the actual operating voltage V (or current I) of the PV array so that the actual power P approaches the optimum value Pmax as closely as possible which will be explained further with reference to FIG. 5.

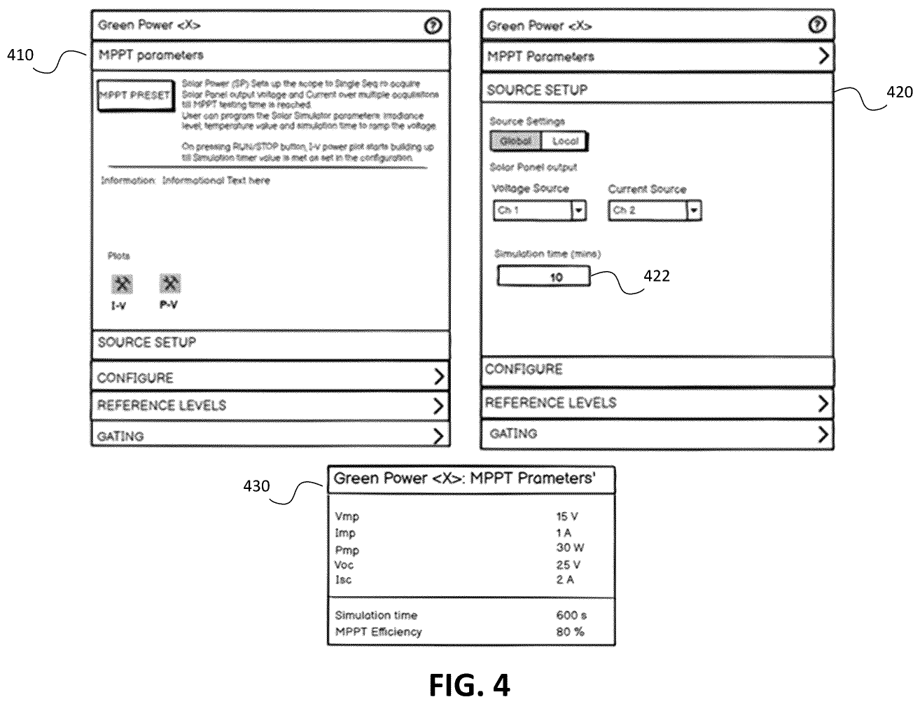

Many ways exist to track the Maximum Power Point (MPP) which can be classified as either direct or indirect methods. Direct methods include algorithms that use measured DC input current and voltage or AC output power values and by varying the PV array operational points, determine the actual MPP. In an aspect of the present disclosure, the direct method is implemented using a controlled environment through simulators and measures the SUT performance parameters such as MPPT timing values, MPPT efficiency, the slope of power vs voltage plot, IV characteristics, short circuit current, and open circuit voltage. When testing the performance of a controller that performs MPPT in a SUT 30, 300, the instrument 10 may display test configuration windows, such as windows 410, 420 shown in FIG. 4, to allow a user to enter one or more test configuration settings. In particular, the user may enter a simulation time value at control 422. Further, the MPPT efficiency is between the initial measured power value to the final power value till the simulation time value (as shown in FIG. 4). Also, the user (or the operator or the designer) can program the solar simulator setup to adjust/modify irradiance level (power), temperature value and coefficient, fluctuations (clouds), and simulation time to ramp the voltage and current levels. Results of the SUT performance measurements may be displayed in a results window, such as results window 430, on the display of the user interface.

Further, if the designer wants to profile the MPPT module/device with the PV array using real scenarios, then the same measurement can be used which is performed for a longer duration (minutes) to reach the same graph on the oscilloscope. During profiling, the designers can look at real-time power quality parameters. Furthermore, on pressing the RUN/STOP button, the MPPT plot (as shown in FIG. 5) in a mixed signal oscilloscope (MSO) starts building up till the simulation timer value 422 is met as set in the configuration. The designer can save the MPPT plot (such as plot 500 as shown in FIG. 5, or plot 600 shown in FIG. 6) which was constructed in real time with an actual PV array and load this curve to a power supply or a PV Simulator which gets into Inverter. The plot values can be saved as CSV (comma-separated values) for post-processing acquisition trend plots.

MPPT Efficiency is the ratio of output to input power. The output voltage and current are measured at DC-DC block and the input is from the solar source to DC-DC block. Typically, the MPPT Efficiency can be observed over an acquisition trend plot for many hours using an oscilloscope 10 with real time data updates as shown in FIG. 1.

Further, the parameters such as, but not limited to, Open circuit voltage (Voc), Short circuit current (Isc), Maximum power voltage (Vmp), and Maximum power current (Imp) are found from the plots (as shown in FIG. 5 and FIG. 6). In particular, the above-mentioned parameters are determined from the plot between power and voltage (FIG. 5), and the plot between voltage and current. (FIG. 6).

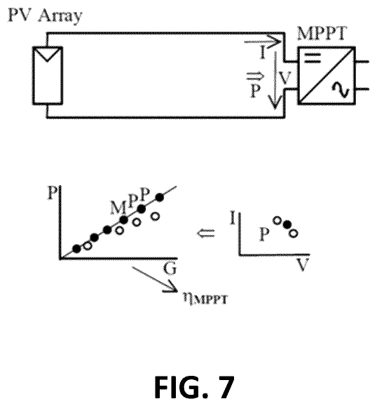

Referring to FIG. 7, there are several approaches for using data collected from operating PV systems to determine the operating accuracy of the MPPT. To a first-order approximation, the MPP current Imax is dependent solely on the in-plane irradiance G. If the MPPT works correctly, the input current (I) should be close to Imax. Oscilloscope will help in testing multiple MPPT algorithms real time like perturb and observe, incremental conductance, any hill climbing method, current sweep, constant voltage, etc. The plot represents the operation of the MPPT device to adjust the Pmax within the MPPT range using different MPPT algorithms. For example, the hill climbing methods will have an equation as depicted below.

$$\frac{dP}{dV} = V * \frac{dI}{dV} + I ( V )$$

The slope of the P-V curve will tend to zero at MPP. So, the slope of the P-V hill is always calculated and adjusted by the device to meet MPP. The oscilloscope capturing voltage and current has to perform the same calculation in real time and plot the expected curve. If required, the oscilloscope can generate a corrective control signal to his MPPT device whenever captured voltage and current falls out of the MPP zone.

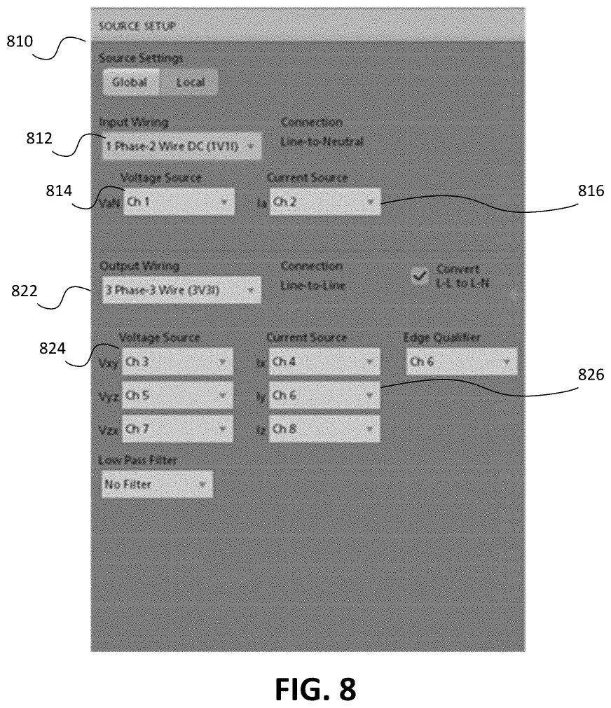

Referring to FIG. 8, efficiency measurement can measure the input and output power. It can be specific blocks such as DC-DC converter, GTI, or it can be the whole system. The measurement takes in input and output sources and their types (AC or DC and wiring). As shown in FIG. 8, when performing an efficiency measurement of at least one component of the SUT 30, 300, the instrument 10 may present a test configuration window 810 to the user. The test configuration window may include settings for an input wiring configuration 812, and an output wiring configuration 822, as well as one or more input voltage sources (i.e. channels) 814, one or more input current sources 816, one or more output voltage sources 824, and one or more output current sources 826. The quantity of input voltage sources 814 and input current sources 816 presented to the user depends on the particular input wiring configuration 812 selected by the user. For example, as shown in the example of FIG. 8, the user has selected the input wiring configuration 812 of “1 Phase-2 Wire DC (1V1I),” which causes window 810 to present one input voltage source 814 (selected as Channel 1 of the instrument 10) and one input current source 816 (selected as Channel 2 of the instrument 10) to the user. Likewise, the quantity of output voltage sources 824 and output current sources 826 presented to the user depends on the particular output wiring configuration 822 selected by the user. For example, as shown in the example of FIG. 8, the user has selected the output wiring configuration 822 of “3 Phase-3 Wire (3V3I),” which causes window 810 to present three output voltage sources 824 (selected as Channels 3, 5, and 7) and three output current sources 826 (selected as Channels 4, 6, and 8) to the user. Based on these inputs, the computation is done. In an embodiment, power is computed using the below equation.

$$Power = \frac{1}{n} {\sum }_{i = 1}^{n} {V}_{i} * {I}_{i} , over complete cycles .$$

Wherein, n is the number of samples, Vᵢ, and Iᵢ are i^{th} samples of voltage and current waveforms respectively.

Furthermore, the efficiency is computed using the below equation.

$$Efficiency = \frac{Total output power}{Total input power} \times 100 \%$$

This measurement can be done on DC-DC converter, or DC-AC converter, or for the whole system 300 as shown in FIG. 3.

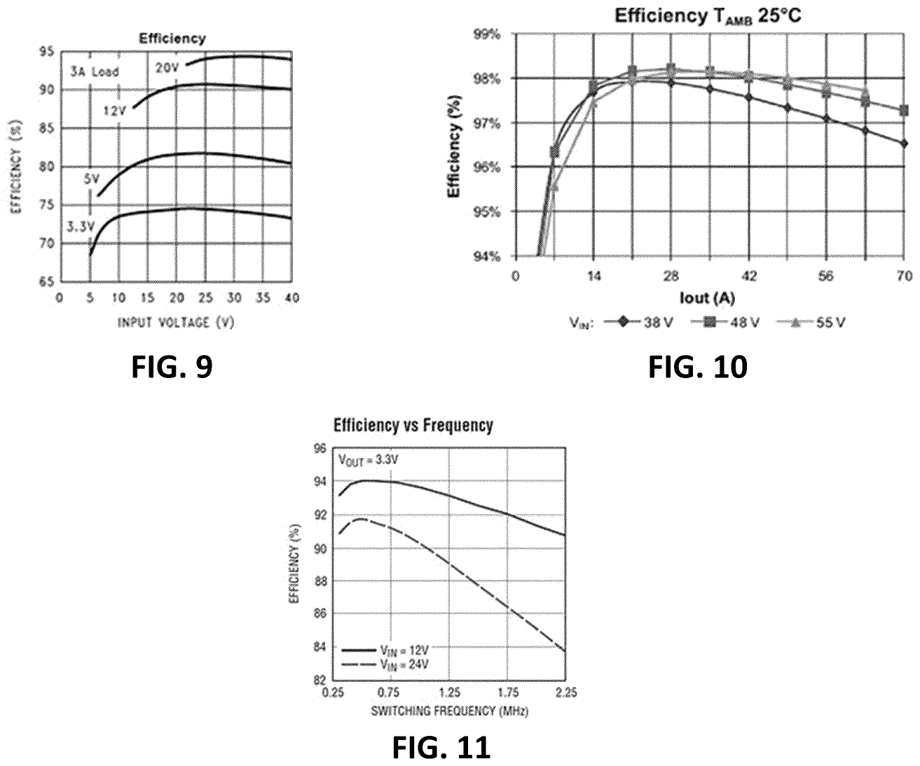

Thereafter, plotting input voltage vs efficiency (as shown in FIG. 9), current vs efficiency (as shown in FIG. 10) and switching frequency of the circuit vs efficiency (as shown in FIG. 11) provides suitable operating region for the system. This results in designing better tuned circuit parameters for high efficiency.

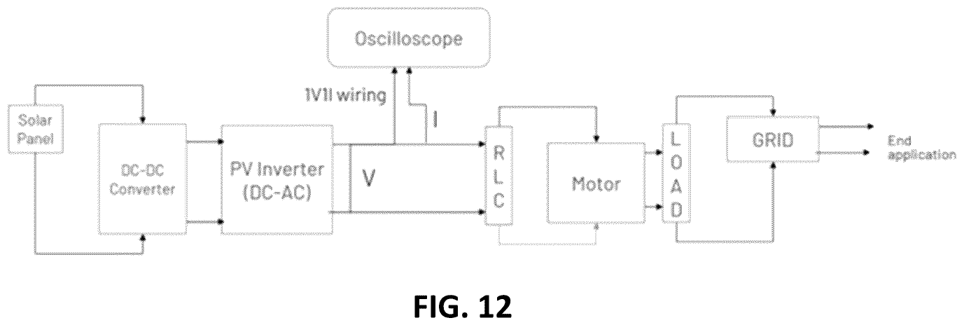

Referring to FIG. 12, islanding refers to the condition of a distributed generator (DG) that continues to feed the circuit with power, even after power from the electric utility grid has been cut off. Generally, the grid-tied inverters are equipped with protective elements for preventing islanding. In particular, the protective elements may be configured to sense when a blackout occurs and disconnect themselves from the grid. This protects the equipment from failure, the grid will be predictable, easier to restore or repair.

It is hard to interpret a power failure. Differentiating power failure from normal fluctuations is crucial. For synchronization, since the voltage is continuously sensed, the same can be utilized to see if the grid is normal, or under failure. Based on that the inverter should be quick to disconnect in case of a failure. Further, oscilloscope measurements can measure the response time based on simulated grid voltage and current. To that effect, anti-islanding can be validated. Anti-islanding is the ability to quickly stop sending power into the grid from your solar power. There are many ways such as passive methods and active methods to validate anti-islanding. The passive methods may include, but are not limited to, standard protective relays, abnormal voltage detection, power factor detection, transient phase detection, phase jump detection (PJD), and the like. The active methods may include, but are not limited to, power shift, current notching, output variation, harmonic distortion jump (THD), over voltage protection (OVP), under voltage protection (UVP).

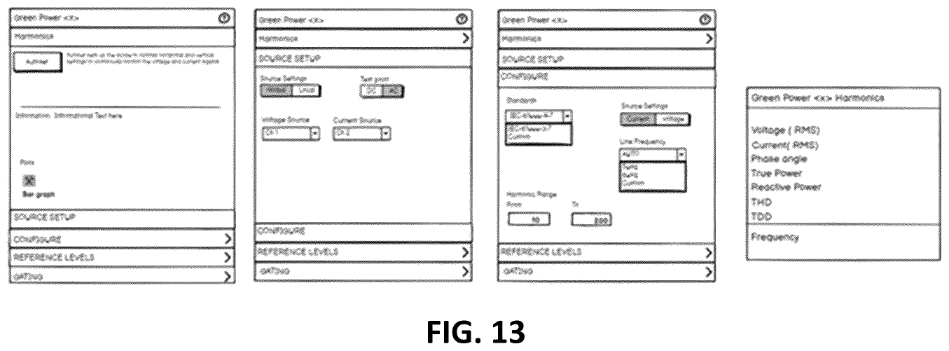

Referring to FIG. 13 in conjunction with FIG. 12, in one implementation of the present disclosure, the THD method is used and is compared against the defined CUSTOM limits. Typically, oscilloscope acquires 3-phase or single-phase voltage and current waveforms from the PV inverter. The measurements will analyze waveforms and compute Total harmonic distortion (THD). Under normal operation, a low-distortion sinusoidal voltage across the load terminals, causing the load to draw an undistorted sinusoidal current across the load terminals, causing the (linear) load to draw an undistorted sinusoidal current. So, the THD will be zero during the initial RUN condition. The designer can monitor the THD values as a plot continuously over time using multiple acquisitions of oscilloscope (as shown in FIG. 13). Further, when the utility disconnects, the harmonic currents produced by the inverter will flow into the load, which in general has much higher impedance than the utility. The harmonic currents interacting with the larger load impedance will produce larger harmonics in the voltage.

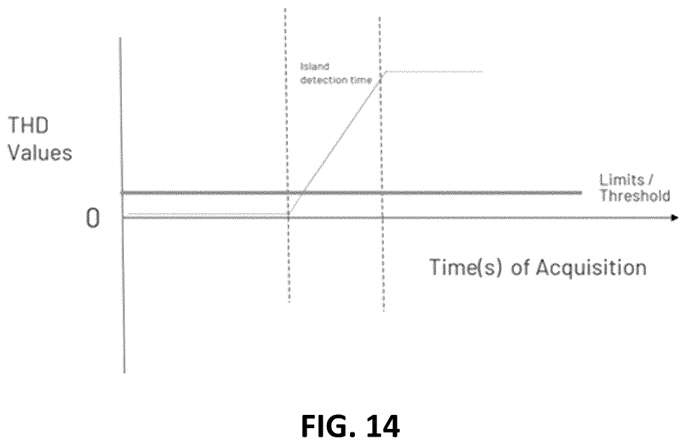

These voltage harmonics, or the change in the level of voltage harmonics, can be detected by the inverter, which can then assume that the PV inverter is islanding and discontinue operation. The designer can define the CUSTOM limits which will be compared with the measured THD values (as shown in FIG. 14). When the THD value exceeds the limits then islanding has been detected (as shown in FIG. 14), and the instrument 10 can alert the user. The limits are defined as in IEEE 1547 standard. For example, the limits defined as in IEEE 1547 standard are shown below in Table 1.

TABLE 1

| | Individual harmonic order, h | | | | | |
|---|---|---|---|---|---|---|
| | | 11 < | 17 < | 23 < | | |
| | h < 11 | h < 17 | h < 23 | h < 35 | 35 ≤ h | TDD |
| Percent (%) | 4.0 | 2.0 | 1.5 | 0.6 | 0.3 | 5.0 |

2 Maximum harmonic current distortion [IEEE 1547, IEEE 519]

FIG. 15 represents a simplified block diagram representation of a test setup 1500 for automation of measurements, in accordance with an embodiment of the present disclosure. The oscilloscope 10 helps in acquisition of data from specific blocks in the system 30, 300, like PV inverter 340, DC-DC converter 320, etc. and gives results and plots from multiple acquisitions. The oscilloscope 10 can acquire the voltage and current waveform and provide real-time measurements. With these real time measurements like power factor, efficiency, crest factor, harmonics, a control signal 1510 is generated from oscilloscope internal AFG 18, which helps in performing hardware in loop simulations with help of automation platform 1520. The oscilloscope 10 may be implemented as a real-time sensing device on one side and a control device on other side. Unlike slower sample rate machines, the control signal 1510 is updated real-time by the oscilloscope 10 to test the complete system. As an example, the control signal 1510 may cause the automation platform 1520 to send instructions to a solar array simulator 1530 to change sun spec settings, or to a grid simulator 1540 to change AC load settings, for different test conditions.

Further, performance testing of grid tied inverter involves the following stages with appropriate standards mentioned. For example, inverter efficiency test is as per IEC 61683, MPPT efficiency test is as Per EN 50530, charge controller performance test is as per IEC 62509, islanding prevention measures for utility interconnected inverter photovoltaic inverters is as per IEC 62116, and Grid Integration Analysis is as per IEEE Std 1547-2018 (Revision of IEEE Std 1547-2003).

In an advantageous aspect, the present disclosure reduces time-to-market by accelerating design cycles and protects investment in test and measurement equipment capital investments by minimizing refresh cycles.

In another advantageous aspect, the present disclosure discloses providing a phase shift in a grid-tied-inverter so as to test and validate synchronization and improve output power and efficiency in the grid-tied-inverter.

In another advantageous aspect, the present disclosure discloses validation of complete ecosystem from component selection to the pre-compliance. This helps in detection of compatibility issues and makes the system ready for compliance testing.

In another advantageous aspect of the present disclosure, continuous tracking and fault detection is enabled by different features supported in the workflow, provides data security in case of failure.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

What is claimed is:

1. An oscilloscope, comprising:
input channels for receiving at least one voltage signal and at least one current signal from an input side or an output side of at least one component of a photovoltaic power system under test (SUT);
a user interface, the user interface including a display, and one or more controls for receiving one or more test configuration settings from a user; and
one or more processors configured to execute code to cause the one or more processors to:
acquire waveforms of the at least one voltage signal and the at least one current signal, and
implement a photovoltaic power system compliance test module to:
automatically determine, in real-time, one or more SUT performance measurements based on the acquired voltage and current waveforms and the one or more test configuration settings, and
display, in real-time, the one or more SUT performance measurements to the user on the display.

2. The oscilloscope according to claim 1, wherein the SUT includes a controller that performs maximum power point tracking (MPPT) for the SUT, and wherein the one or more SUT performance measurements comprise at least one of MPPT timing values, MPPT efficiency, slope of power versus voltage plot, IV characteristics, short circuit current, and open circuit voltage.

3. The oscilloscope according to claim 2, wherein the one or more processors are further configured to execute code to cause the one or more processors to:
generate, in real-time, an MPPT plot using the acquired voltage and current waveforms, and
display the MPPT plot to the user on the display.

4. The oscilloscope according to claim 3, wherein the one or more test configuration settings includes a simulation time, and wherein the MPPT plot is continuously updated until the simulation time elapses.

5. The oscilloscope according to claim 3, wherein the one or more processors are further configured to execute code to cause the one or more processors to save the MPPT plot into a file format for loading into a power supply or photovoltaic (PV) simulator.

6. The oscilloscope according to claim 3, wherein the MPPT plot comprises one or both of a power versus voltage (P-V) plot and a current versus voltage (I-V) plot, and wherein the one or more SUT performance measurements are determined from the MPPT plot, the one or more SUT performance measurements comprising at least one of open circuit voltage (Voc), short circuit current (Isc), maximum power voltage (Vmp), and maximum power current (Imp).

7. The oscilloscope according to claim 2, wherein the one or more SUT performance measurements comprise MPPT efficiency, and wherein the one or more processors are further configured to execute code to cause the one or more processors to repeat the acquiring, automatically determining, and displaying for at least one hour.

8. The oscilloscope according to claim 7, wherein the one or more processors are further configured to execute code to cause the one or more processors to
generate a trend plot of MPPT efficiency, and
display the trend plot to the user on the display.

9. The oscilloscope according to claim 1,
wherein the one or more SUT performance measurements comprise an efficiency measurement of the at least one component of the SUT;
wherein the one or more test configuration settings include an input wiring configuration, one or more input voltage sources, one or more input current sources, an output wiring configuration, one or more output voltage sources, and one or more output current sources; and
wherein a quantity of input voltage sources and input current sources presented to the user is dependent on the input wiring configuration selected by the user, and a quantity of output voltage sources and output current sources presented to the user is dependent on the output wiring configuration selected by the user.

10. The oscilloscope according to claim 9, wherein the one or more processors are further configured to execute code to cause the one or more processors to
generate an efficiency plot, and
display the efficiency plot to the user on the display; and
wherein the efficiency plot comprises at least one of efficiency versus input voltage, efficiency versus output current, and efficiency versus switching frequency.

11. The oscilloscope according to claim 1, wherein the SUT includes an inverter that has anti-islanding circuitry, and wherein the one or more SUT performance measurements includes validating operation of the anti-islanding circuitry.

12. The oscilloscope according to claim 11, wherein validating operation of the anti-islanding circuitry comprises measuring a response time of the anti-islanding circuitry to a simulated grid voltage and a simulated grid current representing a grid failure in the SUT.

13. The oscilloscope according to claim 11, wherein validating operation of the anti-islanding circuitry comprises:
measuring total harmonic distortion (THD) values based on the acquired voltage and current waveforms;
comparing the measured THD values to configurable limits; and
alerting the user when at least one of the measured THD values exceeds a limit.

14. The oscilloscope according to claim 1, further comprising:
an arbitrary function generator (AFG); and
an output port configured to send a control signal from the AFG to a test automation platform.

15. The oscilloscope according to claim 14, wherein the one or more processors are further configured to execute code to cause the one or more processors to instruct the AFG to generate the control signal, in real-time, in response to results of the one or more SUT performance measurements.

16. A method of performing automated hardware-in-the-loop testing of a photovoltaic power system under test (SUT) using an oscilloscope, the method comprising:
receiving a voltage signal associated with at least one component of the SUT at a first input channel of the oscilloscope;
receiving a current signal associated with the at least one component of the SUT at a second input channel of the oscilloscope;
acquiring a voltage waveform from the voltage signal, and acquiring a current waveform from the current signal;
receiving one or more test configuration settings from a user through a user interface;
automatically determining, in real-time, one or more SUT performance measurements based on the acquired voltage and current waveforms and the one or more test configuration settings; and
displaying, in real-time, the one or more SUT performance measurements to the user on the display.

17. The method according to claim 16, further comprising:
generating a control signal using an arbitrary function generator (AFG) of the oscilloscope; and
outputting the control signal from an output port of the oscilloscope to an automation platform to cause a change of settings in the SUT.

18. The method according to claim 16, wherein automatically determining one or more SUT performance measurements comprises determining at least one of inverter efficiency, maximum power point tracking (MPPT) efficiency, charge controller performance, islanding prevention measures, and grid integration analysis.

19. The method according to claim 16, further comprising:
generating, in real-time, a plot based on the acquired voltage waveform and current waveform;
displaying, in real-time, the plot on a display of the oscilloscope;
repeatedly acquiring additional voltage waveforms from the voltage signal, and repeatedly acquiring additional current waveforms from the current signal; and
updating, in real-time, the displayed plot on the display after each additional voltage and current waveform is acquired.

20. The method according to claim 19, wherein the repeatedly acquiring and the updating continues until a user-selectable simulation time has elapsed.
